(19) United States
(12) Patent Application Publication
(10) Pub. No.: US 2024/0161256 A1
(43) Pub. Date: May 16, 2024

(54) SYSTEMS AND METHODS FOR ARBITRARY LEVEL CONTRAST DOSE SIMULATION IN MRI

(71) Applicant: Subtle Medical, Inc., Menlo Park, CA (US)

(72) Inventors: Dayang WANG, Columbia, SC (US); Srivathsa Pasumarthi VENKATA, Santa Clara, CA (US)

(21) Appl. No.: 18/508,403

(22) Filed: Nov. 14, 2023

Related U.S. Application Data
(60) Provisional application No. 63/383,975, filed on Nov. 16, 2022.

(51) Int. Cl. G06T 5/00; G01R 33/56; G06N 3/08; G06T 5/50

(52) U.S. Cl. CPC G06T 5/009; G01R 33/5601; G01R 33/5608; G06N 3/08; G06T 5/50; G06T 2207/10088; G06T 2207/20081; G06T 2207/30016; G06T 2207/30096

(57) ABSTRACT

Methods and systems are provided for simulating images with different dosages. The method comprises: learning a mapping relationship from a post-contrast image to a low-dose image using an iterative method, where learning the mapping comprises generating a plurality of images with intermediate dosages; and applying the mapping relationship to an input images with a higher dose level and a lower dose level to generate one or more simulated images with intermediate dose levels between the higher dose level and the lower dose level.

### CROSS-REFERENCE TO RELATED APPLICATION

This application claims priority to U.S. Provisional Application No. 63/383,975 filed on Nov. 16, 2022, the content of which is incorporated herein in its entirety.

### BACKGROUND

Magnetic Resonance (MR) imaging can provide excellent soft tissue contrast and has been widely used for clinical diagnosis of various diseases. Gadolinium-based contrast agents (GBCAs) have been widely used in the Magnetic Resonance imaging (MRI) exams due to the capability of improving the border delineation and internal morphology of different pathologies and have extensive clinical applications. However, GBCAs have several disadvantages like contraindications in patients with reduced renal function, patient inconvenience, high operation costs and environmental side effects. In order to reduce the dosage level for GBCA injection, deep learning (DL)-based dose reduction approaches have been developed and adopted. However, training a DL model requires high quality low-dose contrast-enhanced (CE) images paired with pre-contrast and full-dose CE images. Acquiring such a dataset may require a modification of the standard imaging protocol (e.g., to acquire various low-dose contrast-enhanced (CE) images) and involve additional training of the MR technicians. It is desirable to simulate the various low-dose images (e.g., process of T1w low-dose image acquisition), using images from the standard protocol. It is also desirable for the dose reduction approaches to establish the minimum dose level required for different pathologies as the minimum dose level is typically dependent on the scanning protocol and the GBCA compound injected.

### SUMMARY

A need exists for a simulation tool that has the ability to synthesize or predict images with multiple contrast enhancement levels, that correspond to multiple arbitrary dose levels. Currently, arbitrary dose simulation method may be based on physics-based models. However, these physics-based methods are dependent on the protocol parameters and the type of GBCA and their relaxation parameters. For example, the contrast perfusion model and contrast quantitative assessment model may be required for simulating arbitrary contrast dose level in an MR image. Deep learning (DL) models have been widely used in medical imaging application due to their high capacity, generazibility, and transferability. However, the performance of these DL models heavily depend on the availability of high quality training data. Different types of GBCAs and pathologies require different dose levels for the DL algorithms to work reliably. It is challenging to develop a deep learning model for simulating images with arbitrary contrast dose level given the lack of diverse ground truth data of the different dose levels.

The present disclosure addresses the above needs by providing a deep learning model-based iterative modelling framework that can synthesize images (e.g., MRI images) with arbitrary contrast enhancement that corresponds to different dose levels (e.g., arbitrary gadolinium dosage or arbitrary contrast dose level). In some embodiments, the deep learning model may comprise a unique global transformer (Gformer) in which the self-attention mechanism can focus more on the global contextual information (e.g., global contrast information) compared to traditional methods. In some embodiments, the transformer may incorporate a sub-sampling based attention mechanism and a rotational shift module that captures various contrast related features. The deep learning (DL) model-based iterative modelling framework may take as input only with pre-contrast images (e.g., images acquired without contrast agent) and post-contrast/full-dose images (e.g., images acquired with full-dose level of contrast agent) MRI images to simulate images with arbitrary contrast enhancement levels. The simulated images can be used downstream tasks such as dose reduction and tumor segmentation to demonstrate the clinical utility. For example, deep learning models may be trained to predict full dose (or higher contrast dose levels) images based on low dose images for contrast-enhancement. This can beneficially allow for dose-reduced MRI due to the safety concerns over the usage of GBCAs. However, in many clinical scenes, there are no or very limited low-dose images or images with various contrast does levels available to train the contrast-enhancement methods. Limited training dataset can result in poor performance of deep learning model. Therefore, simulated MRI images with various contrast dose levels can be used to augment the training dataset and train a deep learning model to reduce the Gadolinium injection.

In an aspect, methods and systems are provided for simulating images with different dosages. The method comprises: learning a mapping relationship from a post-contrast image to a low-dose image using an iterative method, where learning the mapping comprises generating a plurality of images with intermediate dosages; and applying the mapping relationship to an input comprising with a higher dose level and a lower dose level and output one or more simulated image with one or more intermediate dose levels between the higher dose level and the lower dose level.

In an aspect, a computer-implemented method is provided for simulating images with different contrast enhancement levels. The method comprises: providing an iterative model comprising a plurality of iterations, where a given iteration comprises a deep learning model configured to i) take an input comprising a synthesized image generated by a previous iteration, wherein the synthesized image has a first intermediate contrast enhancement level, and ii) output a corresponding synthesized image has a second intermediate contrast enhancement level, wherein the second intermediate contrast enhancement level is lower than the first intermediate contrast enhancement level; and applying the iterative model to a first input image corresponding to a higher contrast enhancement level and a second input image corresponding to a lower contrast enhancement level, and outputting a plurality of synthesized images corresponding to a plurality of intermediate contrast enhancement levels between the higher contrast enhancement level and the lower contrast enhancement.

In a related yet separate aspect, a non-transitory computer-readable storage medium is provided including instructions that, when executed by one or more processors, cause the one or more processors to perform operations comprising: providing an iterative model comprising a plurality of iterations, where a given iteration comprises a deep learning model configured to i) take an input comprising a synthesized image generated by a previous iteration, wherein the synthesized image has a first intermediate contrast enhancement level, and ii) output a corresponding synthesized image has a second intermediate contrast enhancement level, wherein the second intermediate contrast enhancement level is lower than the first intermediate contrast enhancement level; and applying the iterative model to a first input image corresponding to a higher contrast enhancement level and a second input image corresponding to a lower contrast enhancement level, and outputting a plurality of synthesized images corresponding to a plurality of intermediate contrast enhancement levels between the higher contrast enhancement level and the lower contrast enhancement.

In some embodiments, the deep learning model comprises a transformer model. In some cases, the deep learning model comprises a sequence of global transformer blocks. In some instances, at least one of the global transformer blocks comprises a subsample process to generate a sub-image as an attention feature map. For example, the sub-image is sampled at a stride to extract global information from the image data.

In some embodiments, the deep learning model in each iteration is trained based at least in part on a simulated truth image. In some embodiments, the iterative model or the deep learning model is trained utilizing a training dataset comprising a pre-contrast image, a post-contrast image and a low-dose image. In some embodiments, the iterative model or the deep learning model is trained utilizing a training dataset comprising a first image corresponding to a first contrast dose level, a second image corresponding to a second contrast dose level and a third image corresponding to a third contrast dose level, wherein the first contrast dose level is higher than the second contrast dose level which is higher than the third contrast dose level. In some cases, the second image is used as ground truth for the training.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and descriptions are to be regarded as illustrative in nature, and not as restrictive

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 schematically illustrates the learning design of the model.

FIG. 2 shows an example of a base model for a single iteration.

FIG. 3 illustrates an example of the subsampling process and the window attention in the global transformer.

FIG. 4 shows examples of simulated magnetic resonance imaging (MRI) images with different dose level.

FIG. 5 shows examples of simulated magnetic resonance imaging (MRI) images with a tumor.

FIG. 6 shows experiment results of synthesized 10% dose images using different methods.

FIG. 7 shows that the provided model is able to generate images that correspond to different dose levels.

FIG. 8 shows the contrast uptake related quantitative metrics of an experiment result.

FIG. 9 shows visual examples of tumor segmentation performance.

FIG. 10 schematically illustrates a magnetic resonance imaging (MRI) system in which an arbitrary level contrast dose simulator of the presenting disclosure may be implemented.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

### Iterative Model Framework for Dose Simulation Learning

The present disclosure provides a deep learning model-based iterative modelling framework that can synthesize images (e.g., MRI images) with arbitrary contrast enhancement that corresponds to different dose levels (e.g., arbitrary gadolinium dosage or arbitrary contrast dose level). In some embodiments, the deep learning model may comprise a unique global transformer (Gformer) in which the self-attention mechanism can focus more on the global contextual information compared to traditional methods. In some embodiments, the transformer may incorporate a sub-sampling based attention mechanism and a rotational shift module that captures various contrast related features. The DL model-based iterative modelling framework may take as input only with pre-contrast images (e.g., images acquired without contrast agent) and post-contrast/full-dose images (e.g., images acquired with full-dose level of contrast agent) MRI images to simulate images with arbitrary contrast enhancement levels. The arbitrary contrast enhancement levels may be intermediate levels between the pre-contrast enhancement level and the post-contrast level. The simulated images can be used downstream tasks such as dose reduction and tumor segmentation to demonstrate the clinical utility.

In an aspect of the present disclosure, methods and systems are provided for simulating images with multiple contrast enhancement levels, that correspond to multiple arbitrary dose levels. The term “contrast enhancement level” generally refers to the contrast enhancement level shown in the acquired image. The term “dose level” generally refers to a dosage level compared to a standard dosage with a particular protocol. For example, a 10% contrast dose level may refer to 10% of the full dose level under a specific imaging protocol.

In some embodiments, the method comprises: learning a mapping relationship from a post-contrast image to a low-dose image using an iterative method, where learning the mapping comprises generating a plurality of images with intermediate dosages; and applying the mapping relationship to an input image with a first dosage to generate a simulated image with a second dosage, where the second dosage is lower than the first dosage. The method may be capable of taking as input a low-dose image (e.g., MRI images with zero dose level or low-dose) and a post-contrast image (e.g., MRI images with high dose level or full dose level), and generate MRI images of arbitrary gadolinium dosage.

In some embodiments, the present disclosure provides methods for training a vision transformer-based DL model that can synthesize images (e.g., MRI images) that correspond to arbitrary dose levels, utilizing limited dataset. For instance, the DL model may be trained on a highly imbalanced dataset with only pre-contrast image (e.g., zero dose level) and post-contrast image. The post-contrast image may include standard dose or full dose image (e.g., images acquired with standard/full dose level or 100% level, or any higher dose level compared to the low-dose level). In some cases, the training data may comprise a pair of pre-contrast image (e.g., T1w pre-contrast or zero dose level), a low-dose image (e.g., T1w 10% low-dose), and a standard/full dose image (e.g., T1w contrast enhanced standard dose images). The low-dose image may be used as ground truth data and the contrast dose level may be higher than the pre-contrast image. The training method beneficially allows for developing the simulation tool using limited dataset.

In some embodiments, the model backbone for each iteration may comprise a unique Global transformer (Gformer) with subsampling attention that can learn long-range dependencies of contrast uptake features. In some cases, the methods herein may also comprise a rotational shift operation that can further capture the shape irregularity of the contrast uptake regions.

As mentioned above, DL based models tend to perform poorly when the training data is highly imbalanced. Method of the present disclosure may allow for developing a DL utilizing a highly imbalanced dataset such as with only pre-contrast image (e.g., zero dose level) and post-contrast image. The methods herein may provide an iterative model to learn a dosage reduction process. Iterative methods comprise generating fixed steps towards a final solution and generate step-wise intermediate results. In some embodiments, the provided models may be capable of generating synthesized images with arbitrary contrast enhancement levels based on a pair of images with a first acquired image with a pre-contrast enhancement level and a second acquired image with a post-contrast level. The arbitrary contrast enhancement levels may be intermediate levels between the pre-contrast enhancement level and the post-contrast level. In some cases,

[symbol]

The iterative modelling of the present disclosure may be used to perform dose simulation task and train an end-to-end model on a highly imbalanced dataset. The imbalanced dataset may include only pre-contrast image (e.g., zero dose level) and post-contrast image. The post-contrast image may include standard dose or full dose image (e.g., images acquired with standard/full dose level or 100% level). In some cases, the training data may comprise pre-contrast image (e.g., T1w pre-contrast), a low-dose image (e.g., T1w 10% low-dose), and a standard/full dose image (e.g., T1w contrast enhanced standard dose images). This can beneficially allow for developing the simulation model when only T1w pre-contrast, T1w low-dose, and T1w post-contrast images are available.

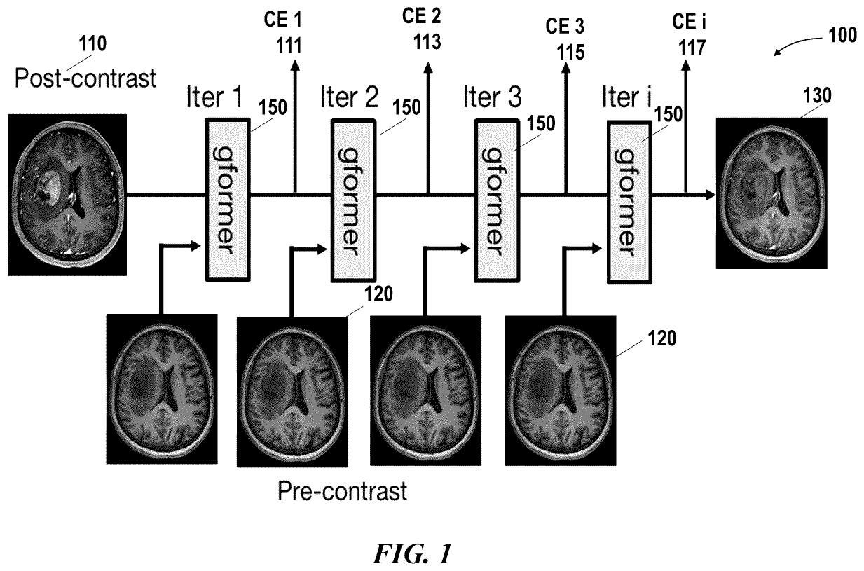

In an aspect of the present disclosure, an iterative model based on iterative learning is provided for learning a dosage reduction process. The iterative model may learn a gradual dose reduction process, in which each iteration step removes a certain amount of contrast enhancement from the full-dose (post-contrast) image. It should be noted that the dosage reduction process may be from a post-contrast image to a pre-contrast image. The post-contrast image may correspond to a contrast enhancement level that may be full-dose 100%, or any other higher level (e.g., 90%, 95%, 99%). The pre-contrast image may correspond to a contrast enhancement level that is substantially low such as zero level or below 10%. FIG. 1 schematically illustrates the iterative learning framework of the model 100. The model learns a mapping from the post-contrast image 110 to the low-dose image 130 with a number of iterations. The model may be trained utilizing paired data set. In some cases, a paired dataset may comprise a pair of post-contrast image 110, a pre-contrast image 120 and a low-dose image 130 as the ground truth data. In some cases, the post-contrast 110 can be any dose level (e.g., 80%, 90%, 100%) that is higher than a dose level of the pre-contrast image 120 and the low-dose image 130. In some cases, the pre-contrast image 120 may include any lower dose level (e.g., 0%, 10%, etc.) so long as it is lower than the dose level of the low-dose image 130. In some cases, the training dataset may comprise a pair of a first image with a first dose level, a second image with a second dose level and a third image with a third dose level, the first dose level is higher than the second dose level which is higher than the third dose level. The second image is used as ground truth in the training dataset.

The whole model performs a dose reduction process. For example, the Gadolinium dosage decreases by a fixed step. The learning design of the iterative model may comprise generating the intermediate dose MRI images 111, 113, 115, 117. The model learns a dosage reduction process, in which each iteration may remove a certain contrast dosage from the input image. In some cases, within each iteration, the higher dosage image and the pre-contrast image are fed to the base model to generate the lower dose image. All the intermediate outputs 111, 113, 115, 117 may correspond to the MRI images of different contrast dosage with a fixed gap (e.g., 90%, 80%, 70%, 60%, 50%, 40%, 30%, 20%, etc.). The step size may be dependent at least in part on the number of iterations.

As shown in FIG. 1, the iterative model 100 G=F○F○ . . . ○F learns a transformation from the post-contrast (e.g., standard/full dose or higher dose level) 110 to the low-dose image (e.g., 10% low-dose) 130 in k iterations, where F represents the base model 150. The base model 150 may be a deep learning model and may also be referred to as backbone model or backbone network which are utilized interchangeably throughout the specification. Details about the backbone or base model are described later herein. At each iteration i, the higher contrast enhancement (CE) image (e.g., CE 1 111) from the previous step and the pre-contrast images 120 are fed into the base model 150 F to predict the image with a lower enhancement (e.g., CE 1 113). The base model in the first iteration may take as input the post-contrast image 110 and the pre-contrast image 120 as input.

In some cases, the iterative model can be formulated as following:

$$\{ \begin{matrix}{\hat{P}}_{i} = F ( ) \\ = \overbrace{{F}_{o} {F}_{o ⋯ o} F} ( {P}_{post} , {P}_{pre} )\end{matrix}$$

where Pₚᵣₑ, Pₚₒₛₜ, and [symbol] represent the pre-contrast, post-contrast, and predicted low-dose images, respectively and [symbol] represents the image with a higher enhancement than \hat{P}ₗ. The intermediate outputs [symbol] having different enhancement levels, correspond to images with different contrast dose level with a uniform interval.

Model convergence and Loss functions: The iterative model may learn a mapping from the post-contrast and pre-contrast images to the synthesized low-dose images. In some cases, the model may be trained with the true 10% low-dose image as the ground truth. An iterative model can be easily susceptible to the gradient explosion/vanishing problem, especially when the iteration number increases. For example, when there are only five iterations, the model can fail to converge to the low-dose image even when all the inputs are well normalized. The present disclosure provides methods that can overcome this problem. For example, the model may adopt the ‘simulated truth’ to serve as soft labels for all the intermediate outputs. In some cases, the soft labels may be generated using linear scaling. The soft labels may serve as a reference to the intermediate outputs during the iterative training process and also aid model convergence (otherwise the model has to directly learn from post-contrast to low-dose subjected to vanishing/explosion). The ‘simulated truth’ can be directly generated by the linear interpolation between post-contrast and pre-contrast images. For instance, given k iterations, the model may generate k outputs Pᵢ, i=1, 2, . . . , k. Then, the simulated truth Sᵢ, i=1, 2, . . . , k−1 for iteration i is calculated as

$${S}_{i} = pre + ( post - pre ) \times \frac{k - i}{k}$$

where pre and post represent the pre-contrast and post-contrast images, respectively. In some cases, the ‘simulated truth’ may not be needed for the last iteration since it will match the true low-dose image.

In some cases, the simulated truth images or soft labels may potentially be subject to misalignment issues by straightforward linear scaling on the contrast uptake. However, they are indispensable to guarantee the convergence of iterative training. In some cases, the soft label images may be generated by processing the pre-contrast and post-contrast using image processing techniques. For example, normalized, affine co-registered may be performed to the post contrast and pre-contrast image. In some cases, depending on the pathology (e.g., brain MRI), additional image processing may be performed. For example, the post contrast and pre-contrast image such as brain MRI images may be skull-stripped (e.g., using entropy-based trilateral filtering to isolate brain tissue from non-brain tissue from an MRI image of a brain) to account for differences in fat suppression. In some cases, the soft labels may be generated by extracting an estimated contrast uptake. Following is an example formular for calculating a soft label {Sᵢ}ᵢ₌₁^{k-1} for iteration i:

$${S}_{i} = {P}_{pre} + [ γ + ( 1 - γ ) \frac{k - i}{k} ] \times ReLU ( - - τ ) .$$

Where [symbol] and [symbol] denote the skull-stripped post-contrast and pre-contrast images. γ=0.1 represents the dose level of the final prediction, and τ=0.1 represents the threshold to extract the estimated contrast uptake U=ReLU ( [symbol] − [symbol] −τ).

The training algorithm may use the L1 and structural similarity index measure (SSIM) losses. Both L1 loss and SSIM loss are calculated on all outputs for model training. Moreover, the VGG19-based perceptual loss and the GAN loss are applied to the final iteration result to further refine the texture in the generated images. In some cases, the simulated truth images or soft labels may serve as ground truth for the intermediate outputs, but only with minor weights so that they may make the model converge but may not overwhelm the real low-dose image in the meantime. An example of the total losses are calculated as

[symbol]

ₜₒₜₐₗ=α·Σᵢ₌₁^{k-1} [symbol] ₑ(\hat{P}ₗ, Sᵢ)+β [symbol] ₑ [symbol] _{low}

Where Lₑ=LL1+L_{SSIM} and α=0.1 and β=1. The soft labels Si are assigned a small loss weight so that they do not overshadow the contribution of the real low-dose image. Additionally, in order to recover the high frequency texture information and to improve the overall perceptual quality, adversarial and perceptual losses are applied on ( [symbol] , P_{low}) with a weight (e.g., weight of 0.1).

Once the model (e.g., sequence of Gformer 150) is trained, the iterative model framework may be deployed to generate synthesized images with arbitrary contrast enhancement levels or contrast dose levels (i.e., inference phase). The arbitrary contrast enhancement levels or contrast dose levels may be intermediate levels between a higher dose level a lower dose level corresponding to a pair of input images. For example, the model may take as input a pair of post-contrast and pre-contrast images, and output a plurality of synthesized images with intermediate dose levels between the full dose level (corresponding to the post-contrast image) and the zero dose level (corresponding to the pre-contrast image). In another example, the input may comprise a pair of images with a first image having a higher contrast enhancement or higher dose level (e.g., 80%, 90%) and a second image having a lower contrast enhancement corresponding to a lower dose level (e.g., 10%, 20%) and the outputted synthesized images may correspond to intermediate dose levels between the higher dose level and the lower dose level. The intermediate dose levels may be at uniform interval between the input images' higher dose level and lower dose level. The number of intermediate images or the interval may be dependent on the number of iterations of the iterative model framework. The input images at the inference phase may comprise a pair of images with a first contrast enhancement (CE) level and a second contrast enhancement level, where the first CE level is higher than the second CE level. The output may include one or more synthesized images with simulated CE level that is between the first CE level and the second CE level. The pair of images at the inference phase may or may not be the same as the CE levels for training the model. For example, the training data may include a pair of pre-contrast (e.g., zero dose) and post-contrast image (e.g., full dose) and a low-dose image as ground truth, whereas the input images for the inference stage may include a higher dose-level image that may or may not be full-dose and a lower dose-level image that may or may not be zero dose.

### Global Transformer Model as a Backbone Architecture

As described above in each iteration, a higher dosage image and the pre-contrast image are fed to a base model to generate the lower dose image or the intermediate image. In some embodiments, the base model may be a unique transformer model. In particular, the transformer model may be improved over traditional Swin transformers which compute attention on non-overlapping local window patches. In some embodiments, a hybrid global transformer (Gformer) is provided as a backbone network (i.e., base model) for the dose simulation task with a self-attention mechanism focussing more on the global contextual information compared to traditional methods.

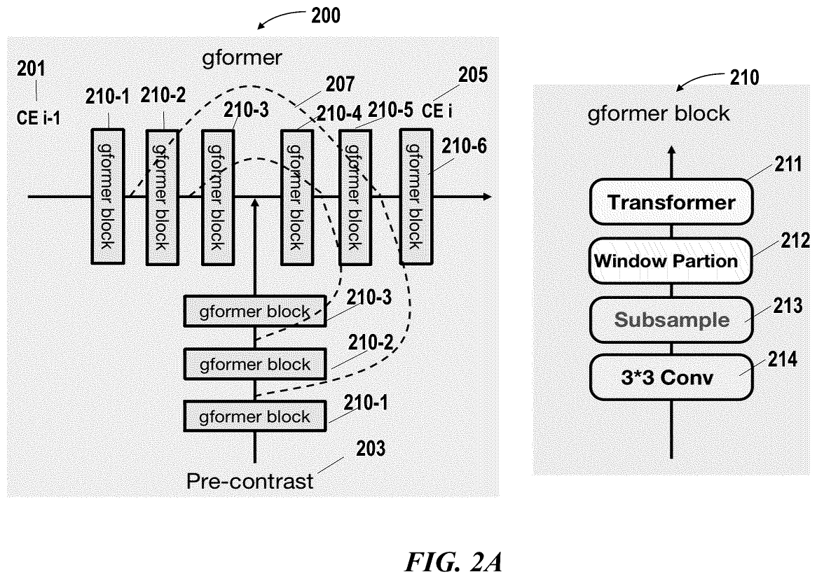

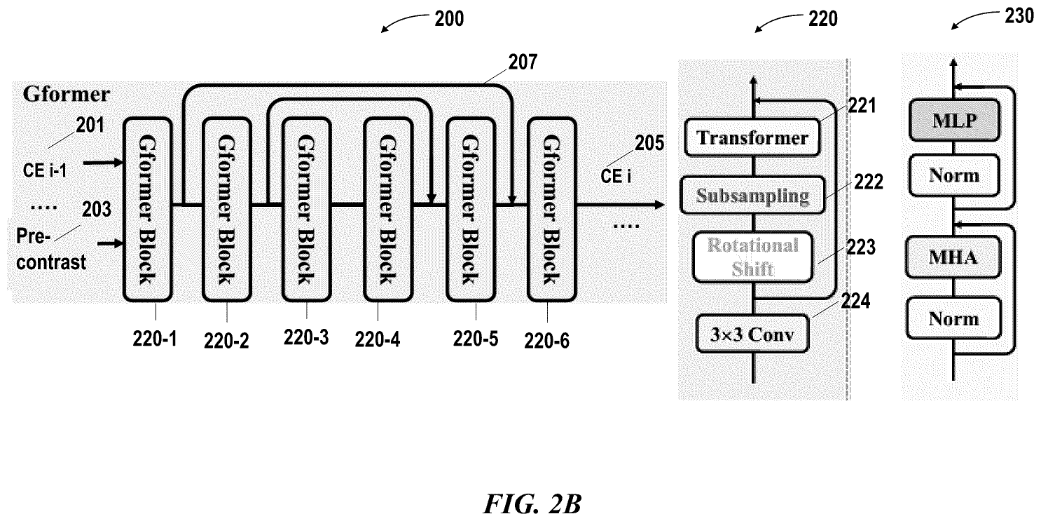

FIGS. 2A-2B show examples of a base model 200 for an iteration. The base model 200 may have a bi-encoder decoder architecture that takes the higher dose image as output from the previous iteration 201 and the pre-contrast image 203 as input and generate the lower dose image 205 as output. Both encoders and decoder include the global transformer (gformer) module as a backbone architecture. In some cases, residual shortcuts 207 are applied to the symmetric level of the encoder-decoder to facilitate image structure preservation. As shown in FIG. 2A or FIG. 2B, the base model 200 may comprise a plurality of Gformer blocks (e.g., six sequential Gformer blocks 210-1, 210-2, 210-3, 210-4, 210-5, 210-6, 220-1, 220-2, 220-3, 220-4, 220-5, 220-6) as the backbone module with shortcuts 207. The base model may comprise any number of Gformer blocks to form the encoder and decoder architecture.

The Gformer block or the transformer model 210 may take the multiple head self-attention as a backbone module. The provided transformer model may focus on the diversity of the windows where the attention is performed. In some cases, the transformer model herein 210 may be an improved hybrid global transformer (gformer) for the dosage simulation task. As illustrated in FIG. 2A, the basic block of a gformer 210 may comprise a convolution block 214, a subsample process 213, a window partition process 212, and a typical transformer module 211. In some cases, the convolution 214 can extract local information while the self-attention may emphasize more on the global contextual information compared with other models such as the Swin transformer. The transformer module 211 can be the same as the transformer network 230 as shown in FIG. 2B. for example, the transformer network 230 may comprise multi-head attention (MHA) mechanism.

FIG. 2B shows another example architecture of a Gformer block 220. The Gformer block 220 may comprise a convolution block 224, a rotational shift module 223, a sub-sampling process 222, and a typical transformer module 221. The convolution layer 224 extracts granular local information of the contrast uptake while the self-attention (e.g., MHA) of the transformer 221 emphasizes more on the coarse global context, thereby paying attention to the overall contrast uptake structure. The transformer module 221 may have a network architecture 230 as shown in FIG. 2B. The convolution block 224, sub-sampling process 222, and the typical transformer module 221 can be the same as those in the Gformer block 210 in FIG. 2A.

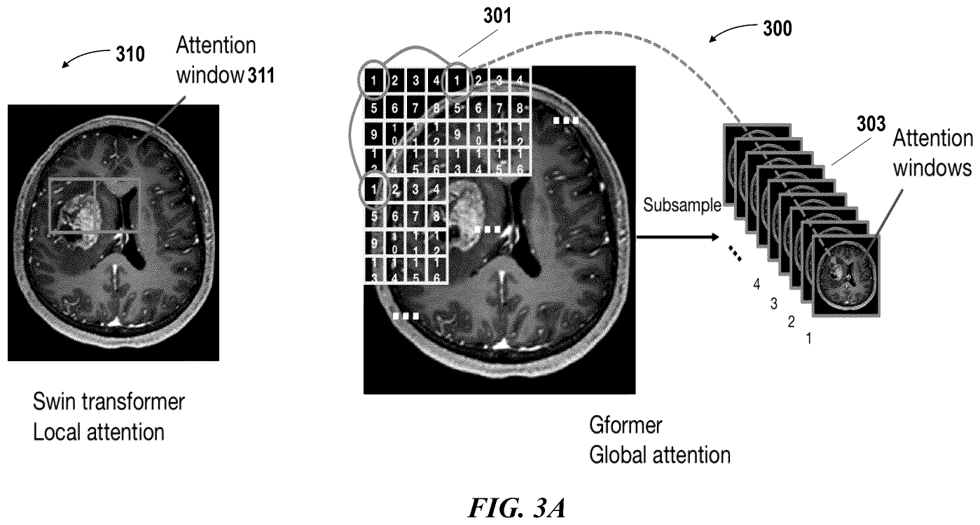

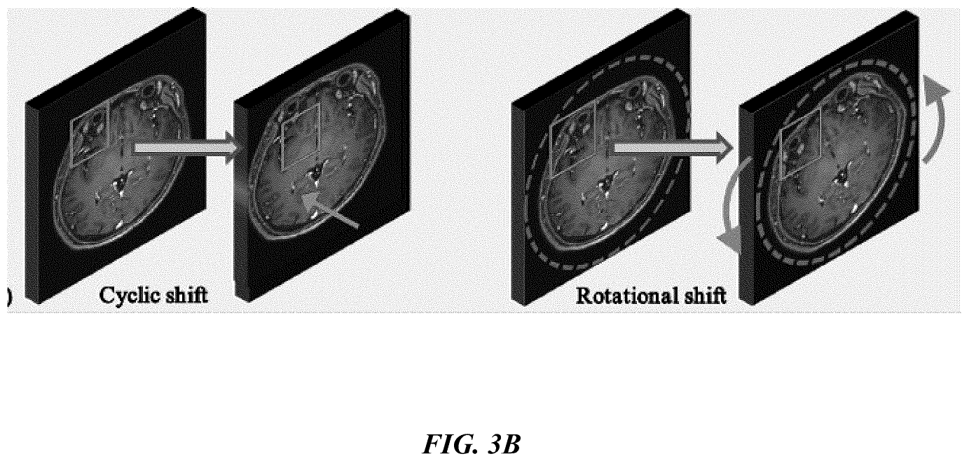

Subsampling attention: The transformer model may comprise a unique subsampling process 212, 222 to perform attention in the subsampled images which beneficially include diverse global information. FIG. 3A illustrates an example of the subsampling process 300 and the window attention 303 in the global transformer (Gformer) global attention. Compared to the local attention 311 in the Swin transformer 310, the Gformer or the provided transformer performs attention in the subsampled images 303 that include diverse global information from the whole image. As shown in FIG. 3A, a number of (e.g., 16) sub-images (e.g., sub-images of 64×64) are generated as the attention windows 303. The Gformer performs attention on subsampled images that include various global information from the original image 301.

The plurality of sub-images 303 are sampled from the whole image which contain global contextual information with minimal self-attention overhead on small feature maps. In some cases, all pixels with the same number may aggregate to the same sub-image. Given the entire feature map Mₑ∈R^{b×c×h×w}, where b, c, h, and w represent the batch size, channel dimension, height, and width, respectively, the subsampling process aggregates the strided positions (in the example illustrated in FIG. 3A, the stride size is 4) to the sub-feature maps as follows:

{Mₛ}ₛ₌₀^{d}^{²}⁻¹={M[:, :, i: h: d, j: w: d]}_{i=0,j=0}^{d-1,d-1}
where d represents sampling a position every d pixels, and Mₛ ER^{b×c×h/d×h/d} is the subsampled feature map. In some cases, the attention feature map for each of the sequence of Gformer blocks may have a corresponding subsampling stride. For example, the subsampling stride for the sequence of six of Gformer block (e.g., 210-1, 210-2, 210-3, 210-4, 210-5, 210-6, 220-1, 220-2, 220-3, 220-4, 220-5, 220-6)) may be {4,8,16,16,8,4}. The method can set h, d=0 to avoid any information loss during subsampling. These d² sub-feature maps are stacked onto the batch dimension as the attention windows 303 for the transformer block.

Rotational shift In some embodiments, the Gformer model may comprise rotational shift to further capture the heterogeneous nature of the contrast uptake areas. In some cases, to prevent information loss on the edges due to rotation, only small angles (e.g., 10°, 20°) may be used for rotation and residual shortcuts are also applied. As an example, the rotational shift angles may be {0, 10, 20, 20, 10, 0} for the sequential Gformer blocks. For example, given the feature map Mo∈R^{b×c×h×w}, rotational shift is performed around the vertical axis of height/width. The rotated feature map Mr∈R^{b×c×h×w} is obtained by the following equation:

$$[ \begin{matrix}{p}^{′} \\ {q}^{′} \\ {x}^{′} \\ {y}^{′}\end{matrix} ] = [ \begin{matrix}1 & 0 & 0 & 0 \\ 0 & 1 & 0 & 0 \\ 0 & 0 & cos λ - & sin λ \\ 0 & 0 & sin λ & cos λ\end{matrix} ] [ \begin{matrix}p \\ q \\ x - h // 2 \\ y - w // 2\end{matrix} ] + [ \begin{matrix}p \\ q \\ h // 2 \\ w // 2\end{matrix} ]$$

Mᵣ(p, q, x, y)={Mₒ(p′, q′, └x′┘, └y′┘), if x′ϵ[0, h) and y′∈[0, w)0, otherwise,}

Where λ is the rotation angle. (p, q, x, y) and (p′, q′, x′, y′) represent the pixel index in the feature map tensor before and after rotational shift, respectively. FIG. 3B illustrates the rotational shift can enhance diverse contextual information fusion across layers compared to cyclic shift in Swin transformer.

### Experiment and Examples

### Experiment 1

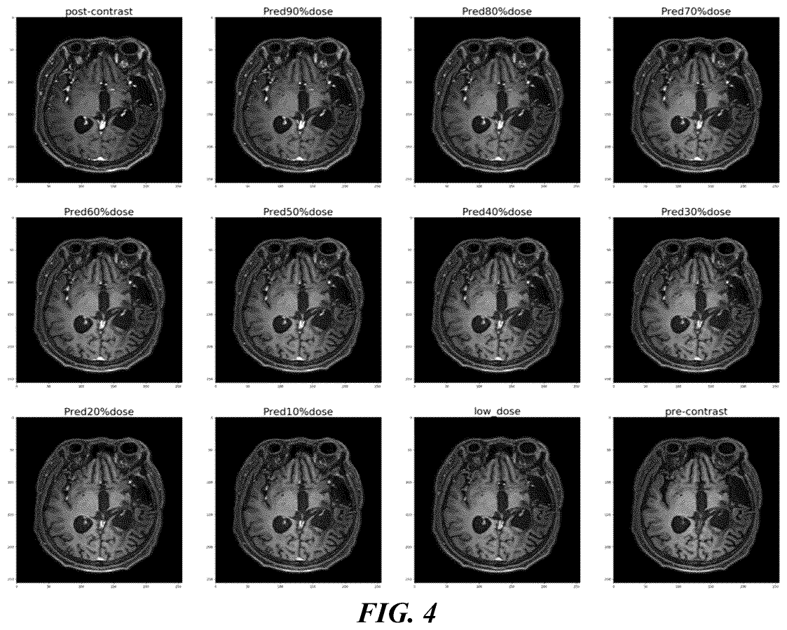

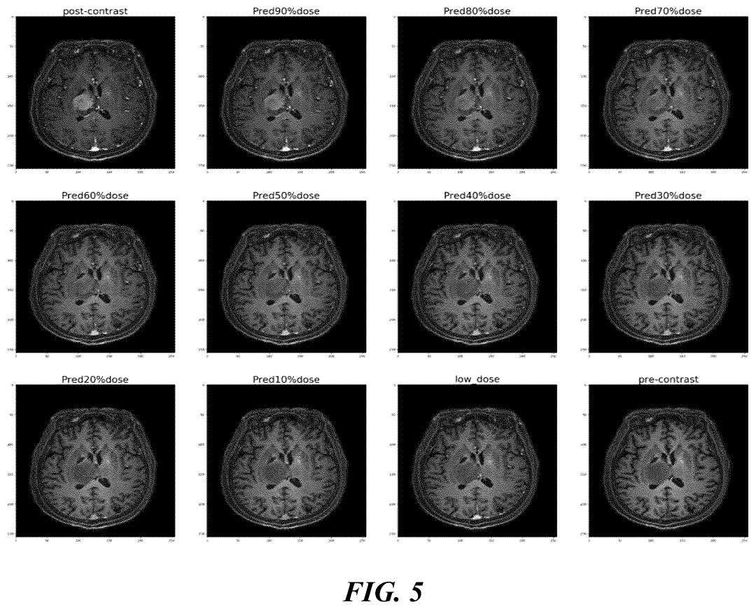

FIG. 4 shows examples of simulated MRI images with different dose levels (e.g., 10%, 20%, 30%, 40%, 50%, 60%, 70%, 80%, 90%). The examples in FIG. 4 illustrates that the proposed model can generate clear and perceptual-pleasing MRI images that correspond to different dosages. FIG. 5 shows examples of simulated MRI images with a tumor inside. The results on the tumor in FIG. 5 show that the model can preserve the tumor texture well while decreasing the Gadolinium contrast. Quantitative results in the following table also show that the proposed Gformer achieves the best scores in terms of peak signal-to-noise ratio (PSNR), structural similarity (SSIM), and root mean square error (RMSE). The table shows quantitative results on the predicted 10% dosage image and the real low-dose image (original).

| | PSNR | SSIM | RMSE |
|---|---|---|---|
| Original | 35.2493 | 0.9579 | 0.0179 |
| CNN | 45.0895 | 0.9881 | 0.0060 |
| Gformer | 45.7030 | 0.9887 | 0.0056 |

### Experiment 2

Dataset: In an experiment, the dataset includes 126 clinical cases (113 training, 13 testing) from an internal private dataset using Gadoterate meglumine contrast agent (Site A). For downstream task assessment, 159 patient studies from another site (Site B) using Gadobenate dimeglumine are used. The clinical indications for both sites included suspected tumor, post-op tumor follow-up and routine brain. For each patient, 3D T1w scans were acquired for the pre-contrast, low-dose, and post-contrast images. These paired images were mean normalized and affine co-registered (pre-contrast as the fixed image). The images were also skull-stripped, to account for differences in fat suppression, using a brain extraction tool for generating the “soft labels”.

Implementation details: All experiments were conducted with a single 32 GB GPU on an Intel® Xeon® CPU. The Subsampling stride for the six levels of Gformer block were {4, 8, 16, 16, 8, 4}. The Rotational shift angles were {0, 10, 20, 20, 10, 0} across all blocks. The model was optimized using the Adam optimizer with an initial learning rate of 1e-5 and a batch size of 4.

Evaluation settings: The provided model is quantitatively evaluated using PSNR, SSIM, RMSE, and LPIPS perceptual metrics, and compared between the synthesized and true low-dose images. The quantitative evaluation includes replacing the Gformer backbone with other state-of-the-art methods to compare the efficacy of the different methods. Particularly, the following backbone networks were studied: simple linear scaling (“Scaling”) approach, Rednet [, Mapnn, Restormer, and SwinIR. Unet and Swin-Unet models were not assessed due to their tendency to synthesize blurry artifacts in the iterative modelling framework. throughput metric (number of images generated per second) was also calculated to assess the inference efficiency.

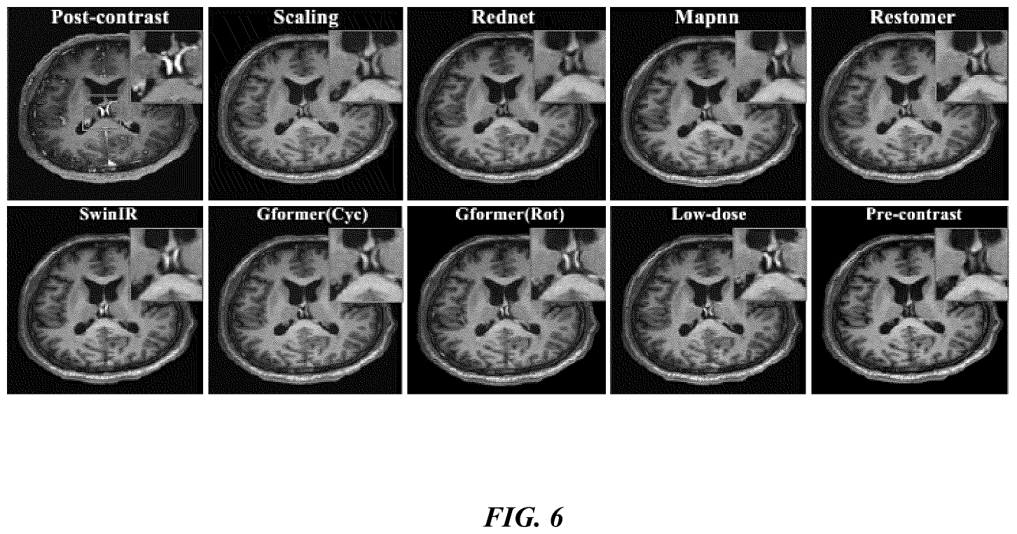

Evaluation results: FIG. 6 shows the results of the synthesized 10% dose images from different methods. ‘Rot’ represents rotational shift and ‘Cyc’ indicates cyclic shift. FIG. 6 and the following table show that provided model can synthesize enhancement patterns that look close to the true low-dose image and that it performs better than the other competing methods with a reasonable inference throughput.

| Method | Throughput | PSNR (dB)↑ | SSIM↑ | RMSE↓ | LPIPS↓ |
|---|---|---|---|---|---|
| Post | — | 33.93 ± 2.88 | 0.93 ± 0.03 | 0.34 ± 0.13 | 0.055 ± 0.016 |
| Scaling | 0.79 Im/s | 38.41 ± 2.22 | 0.94 ± 0.19 | 0.20 ± 0.05 | 0.027 ± 0.015 |
| Rednet | 0.71 Im/s | 40.07 ± 2.72 | 0.97 ± 0.01 | 0.17 ± 0.05 | 0.029 ± 0.009 |
| Mapnn | 0.71 Im/s | 40.56 ± 1.64 | 0.96 ± 0.01 | 0.16 ± 0.05 | 0.023 ± 0.012 |
| Restormer | 0.65 Im/s | 40.04 ± 2.27 | 0.95 ± 0.01 | 0.16 ± 0.16 | 0.038 ± 0.016 |
| SwinIR | 0.58 Im/s | 40.93 ± 2.25 | 0.96 ± 0.01 | 0.15 ± 0.06 | 0.028 ± 0.015 |
| Gformer*(Cyc) | 0.69 Im/s | 41.46 ± 2.14 | 0.97 ± 0.02 | 0.14 ± 0.04 | 0.021 ± 0.007 |
| Gformer*(Rot) | 0.65 Im/s | 42.29 ± 0.02 | 0.98 ± 0.01 | 0.13 ± 0.03 | 0.017 ± 0.005 |

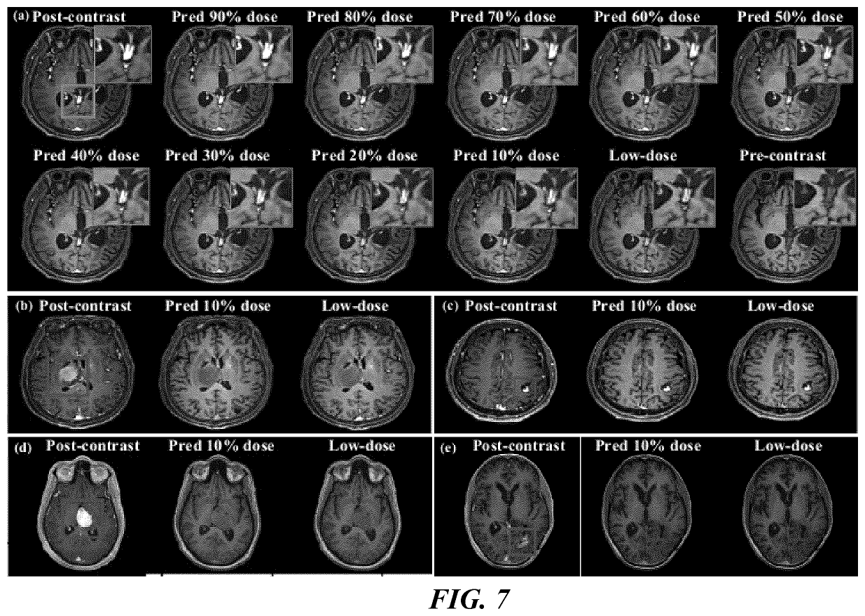

FIG. 7 shows that the provided model is able to generate images that correspond to different dose levels. Panel (a) shows model results about images with different contrast enhancement corresponding to different dose levels along with the synthesized and true low-dose and pre-contrast. As shown in the zoomed inset the hyperintensity of the contrast uptake in these images gradually reduces at each iteration. FIG. 7 (panel b) shows that the pathological structure in the synthesized low-dose image is similar to that of the ground truth image. FIG. 7 (panel c) also shows that the model is robust to hyperintensities that are not related to contrast uptake. As shown in the images, (b)-(c) are two representative slices of the synthesized 10% dose images, (d)-(e) are two representative slices using a different GBCA.

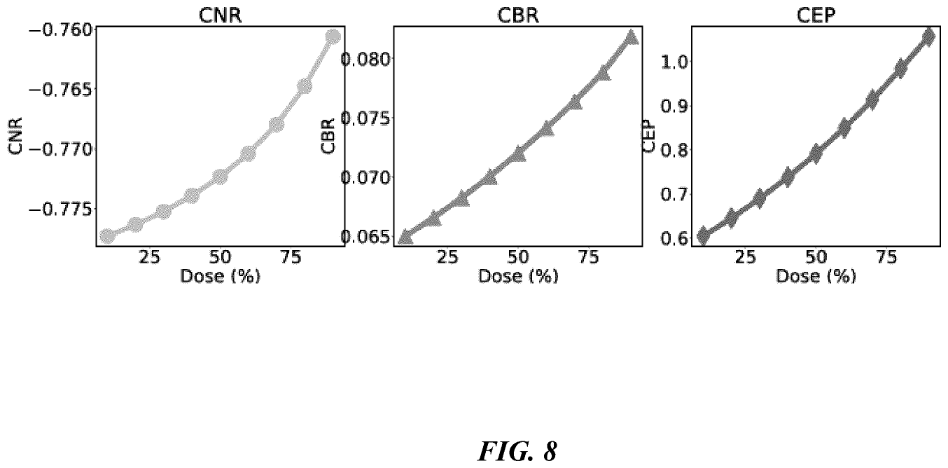

Quantitative assessment of contrast uptake: The above pixel-based metrics do not specifically focus on the contrast uptake region. The following metrics are used to assess the contrast uptake patterns of the intermediate images: contrast to noise ratio(CNR), contrast to background ratio(CBR), and contrast enhancement percentage(CEP). The ROI for the contrast uptake was computed as the binary mask of the corresponding “soft labels”. As shown in FIG. 8, the value of the contrast specific metrics increases in a non-linear fashion as the iteration step increases.

Downstream tasks: In order to demonstrate the clinical utility of the synthesized low-dose images, the experiment performed two downstream tasks. A first task is low-dose to full-dose synthesis. This task used the DL-based algorithm to predict full-dose image from pre-contrast and low-dose images, T1CE volumes were synthesized using true low-dose (T1CE-real-ldose) and Gformer (rot) synthesized low-dose (T1CE-synth-ldose). The experiment computed the PSNR and SSIM metrics of T1CE vs T1CE-synth/T1CE vs T1CE-synth-sim which are 29.82±3.90 dB/28.10±3.20 dB and 0.908±0.031/0.892±0.026 respectively. This shows that the synthesized low-dose images perform similar to that of the low-dose image in the dose reduction task. For this analysis, data from Site B were used. FIG. 8 shows the contrast uptake related quantitative metrics.

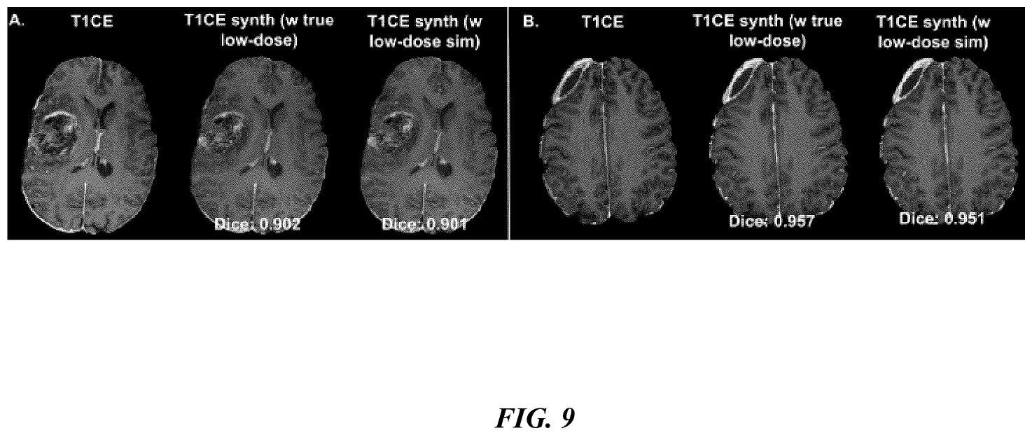

The second task is tumor segmentation. This task used the T1CE volumes synthesized in the above step, performing tumor segmentation using the winning solution of BraTS 2018 challenge. Let Mₜᵣᵤₑ, M_{ldose} and M_{ldose-sim} be the whole tumor (WT) masks generated using T1CE, T1CE-real-ldose and T1CE-synth-ldose (+T1, T2 and FLAIR images) respectively. The mean Dice scores Dice (Mₜᵣᵤₑ, M_{ldose}) and Dice(Mₜᵣᵤₑ, M_{ldose-sim}) on the test set were 0.889±0.099 and 0.876±0.092 respectively. FIG. 9 shows visual examples of tumor segmentation performance. The tumor segmentation (green overlay) on synthesized T1CE using real and simulated low-dose is compared to the tumor segmentation on ground truth T1CE. The corresponding Dice scores are also shown in the bottom. This shows that the clinical utility provided by the synthesized low-dose is similar to that of the actual low-dose image.

### System Overview

It should be noted that though the simulation methods of the present disclosure are illustrated in the context of MRI, brain MRI, and Gadolinium-based contrast agents (GBCAs), the simulation methods and frameworks can be applied to any other anatomies, imaging modalities and contrast agents. The present disclosure provides an arbitrary level contrast dose simulation method and system. The methods and systems herein may generate synthesized or simulated images with arbitrary contrast dose level. As described above, the method may provide an iterative model to simulate the MRI images with different dosages. Also, the method comprises a new transformer model to learn the dose reduction process by encompassing both local and global information. The transformer model may learn the dose reduction process by leveraging the pre-contrast and the post-contrast images. The deep learning model of the present disclosure may be capable of simulating MRI images with arbitrary dosage.

The methods and systems herein can be applied for various purposes and applications. The synthesized images can beneficially assist the clinical diagnosis and be used for contrast enhancement in the dose-reduced MRI, and various other downstream applications. Simulated images generated by the methods and systems herein may be used to train various models to perform various downstream applications. For example, the methods and systems may be used to reduce contrast agent dose, generate MRI images that can be further used to assist the clinical diagnosis with richer demonstration. Additionally, the simulated low-dose image can be used in contrast enhancement in the dose-reduced MRI. The arbitrary level doses can also beneficially allow for power analysis to determine the amount of low-dose sufficient for each type of pathology. Though MRI and MR data examples are primarily provided herein, it should be understood that the present approach may be used in other imaging modality contexts. For instance, the presently described approach may be employed on data acquired by other types of tomographic scanners including, but not limited to, positron emission tomography (PET), computed tomography (CT), single photon emission computed tomography (SPECT) scanners, functional magnetic resonance imaging (fMRI), and the like.

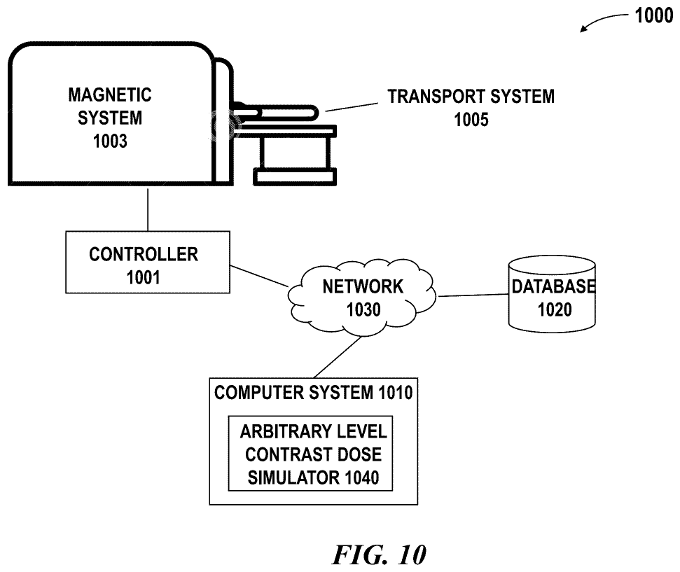

FIG. 10 schematically illustrates a magnetic resonance imaging (MRI) system 1000 in which an arbitrary level contrast dose simulator 1040 of the presenting disclosure may be implemented. The MRI system 1000 may comprise a magnet system 1003, a patient transport table 1005 connected to the magnet system, and a controller 1001 operably coupled to the magnet system. In one example, a patient may lie on the patient transport table 2=1005 and the magnet system 1003 would pass around the patient. The controller 1001 may control magnetic fields and radio frequency (RF) signals provided by the magnet system 1003 and may receive signals from detectors in the magnet system 1003.

The MRI system 1000 may further comprise a computer system 1010 and one or more databases operably coupled to the controller 1001 over the network 1030. The computer system 1010 may be used for implementing the arbitrary level contrast dose simulator 1040. The volumetric MR imaging enhancer 1040 may implement the iterative model framework, Gformer and other methods described elsewhere herein. The computer system 1010 may be used for generating an imaging enhancer using training datasets. Although the illustrated diagram shows the controller and computer system as separate components, the controller and computer system can be integrated into a single component.

The computer system 1010 may comprise a laptop computer, a desktop computer, a central server, distributed computing system, etc. The processor may be a hardware processor such as a central processing unit (CPU), a graphic processing unit (GPU), a general-purpose processing unit, which can be a single core or multi core processor, or a plurality of processors for parallel processing. The processor can be any suitable integrated circuits, such as computing platforms or microprocessors, logic devices and the like. Although the disclosure is described with reference to a processor, other types of integrated circuits and logic devices are also applicable. The processors or machines may not be limited by the data operation capabilities. The processors or machines may perform 512 bit, 256 bit, 128 bit, 64 bit, 32 bit, or 16 bit data operations.

The MRI system 1000 may include one or more databases 1020 that may utilize any suitable database techniques. For instance, structured query language (SQL) or “NoSQL” database may be utilized for storing the reconstructed image data, raw collected data, training datasets, trained model (e.g., hyper parameters), weighting coefficients, rotation angles, Gformer model parameters, etc. Some of the databases may be implemented using various standard data-structures, such as an array, hash, (linked) list, struct, structured text file (e.g., XML), table, JSON, NOSQL and/or the like. Such data-structures may be stored in memory and/or in (structured) files. In another alternative, an object-oriented database may be used. Object databases can include a number of object collections that are grouped and/or linked together by common attributes; they may be related to other object collections by some common attributes. Object-oriented databases perform similarly to relational databases with the exception that objects are not just pieces of data but may have other types of functionality encapsulated within a given object. If the database of the present disclosure is implemented as a data-structure, the use of the database of the present disclosure may be integrated into another component such as the component of the present invention. Also, the database may be implemented as a mix of data structures, objects, and relational structures. Databases may be consolidated and/or distributed in variations through standard data processing techniques. Portions of databases, e.g., tables, may be exported and/or imported and thus decentralized and/or integrated.

The network 1030 may establish connections among the components in the MRI platform and a connection of the MRI system to external systems. The network 1030 may comprise any combination of local area and/or wide area networks using both wireless and/or wired communication systems. For example, the network 1030 may include the Internet, as well as mobile telephone networks. In one embodiment, the network 1030 uses standard communications technologies and/or protocols. Hence, the network 1030 may include links using technologies such as Ethernet, 802.11, worldwide interoperability for microwave access (WiMAX), 2G/3G/4G/5G mobile communications protocols, InfiniBand, PCI Express Advanced Switching, etc. Other networking protocols used on the network 1030 can include multiprotocol label switching (MPLS), the transmission control protocol/Internet protocol (TCP/IP), the User Datagram Protocol (UDP), the hypertext transport protocol (HTTP), the simple mail transfer protocol (SMTP), the file transfer protocol (FTP), and the like. The data exchanged over the network can be represented using technologies and/or formats including image data in binary form (e.g., Portable Networks Graphics (PNG)), the hypertext markup language (HTML), the extensible markup language (XML), etc. In addition, all or some of links can be encrypted using conventional encryption technologies such as secure sockets layers (SSL), transport layer security (TLS), Internet Protocol security (IPsec), etc. In another embodiment, the entities on the network can use custom and/or dedicated data communications technologies instead of, or in addition to, the ones described above.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

As used herein A and/or B encompasses one or more of A or B, and combinations thereof such as A and B. It will be understood that although the terms “first,” “second,” “third” etc. are used herein to describe various elements, components, regions and/or sections, these elements, components, regions and/or sections should not be limited by these terms. These terms are merely used to distinguish one element, component, region or section from another element, component, region or section. Thus, a first element, component, region or section discussed herein could be termed a second element, component, region or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof.

Reference throughout this specification to “some embodiments,” or “an embodiment,” means that a particular feature, structure, or characteristic described in connection with the embodiment is included in at least one embodiment. Thus, the appearances of the phrase “in some embodiment,” or “in an embodiment,” in various places throughout this specification are not necessarily all referring to the same embodiment. Furthermore, the particular features, structures, or characteristics may be combined in any suitable manner in one or more embodiments

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

What is claimed is:

1. A computer-implemented method for simulating images with different contrast enhancement levels, the computer-implemented method comprising:
providing an iterative model comprising a plurality of iterations, wherein a given iteration comprises a deep learning model configured to i) take an input comprising a synthesized image generated by a previous iteration, wherein the synthesized image has a first intermediate contrast enhancement level, and ii) output a corresponding synthesized image has a second intermediate contrast enhancement level, wherein the second intermediate contrast enhancement level is lower than the first intermediate contrast enhancement level; and
applying the iterative model to a first input image corresponding to a higher contrast enhancement level and a second input image corresponding to a lower contrast enhancement level, and outputting a plurality of synthesized images corresponding to a plurality of intermediate contrast enhancement levels between the higher contrast enhancement level and the lower contrast enhancement.

2. The computer-implemented method of claim 1, wherein the deep learning model comprises a transformer model.

3. The computer-implemented method of claim 2, wherein the deep learning model comprises a sequence of global transformer blocks.

4. The computer-implemented method of claim 3, wherein at least one of the global transformer blocks comprises a subsample process to generate a sub-image as an attention feature map.

5. The computer-implemented method of claim 4, wherein the sub-image is sampled at a stride to extract global information from the image data.

6. The computer-implemented method of claim 1, wherein the deep learning model in each iteration is trained based at least in part on a simulated truth image.

7. The computer-implemented method of claim 1, wherein the iterative model or the deep learning model is trained utilizing a training dataset comprising a pre-contrast image, a post-contrast image and a low-dose image.

8. The computer-implemented method of claim 1, wherein the iterative model or the deep learning model is trained utilizing a training dataset comprising a first image corresponding to a first contrast dose level, a second image corresponding to a second contrast dose level and a third image corresponding to a third contrast dose level, wherein the first contrast dose level is higher than the second contrast dose level which is higher than the third contrast dose level.

9. The computer-implemented method of claim 8, wherein the second image is used as ground truth for the training.

10. The computer-implemented method of claim 1, wherein the first input image or the second input image is acquired by a transforming magnetic resonance (MR) device.

11. A non-transitory computer-readable storage medium including instructions that, when executed by one or more processors, cause the one or more processors to perform operations comprising:
providing an iterative model comprising a plurality of iterations, wherein a given iteration comprises a deep learning model configured to i) take an input comprising a synthesized image generated by a previous iteration, wherein the synthesized image has a first intermediate contrast enhancement level, and ii) output a corresponding synthesized image has a second intermediate contrast enhancement level, wherein the second intermediate contrast enhancement level is lower than the first intermediate contrast enhancement level; and
applying the iterative model to a first input image corresponding to a higher contrast enhancement level and a second input image corresponding to a lower contrast enhancement level, and outputting a plurality of synthesized images corresponding to a plurality of intermediate contrast enhancement levels between the higher contrast enhancement level and the lower contrast enhancement.

12. The non-transitory computer-readable storage medium of claim 11, wherein the deep learning model comprises a transformer model.

13. The non-transitory computer-readable storage medium of claim 12, wherein the deep learning model comprises a sequence of global transformer blocks.

14. The non-transitory computer-readable storage medium of claim 13, wherein at least one of the global transformer blocks comprises a subsample process to generate a sub-image as an attention feature map.

15. The non-transitory computer-readable storage medium of claim 14, wherein the sub-image is sampled at a stride to extract global information from the image data.

16. The non-transitory computer-readable storage medium of claim 11, wherein the deep learning model in each iteration is trained based at least in part on a simulated truth image.

17. The non-transitory computer-readable storage medium of claim 11, wherein the iterative model or the deep learning model is trained utilizing a training dataset comprising a pre-contrast image, a post-contrast image and a low-dose image.

18. The non-transitory computer-readable storage medium of claim 11, wherein the iterative model or the deep learning model is trained utilizing a training dataset comprising a first image corresponding to a first contrast dose level, a second image corresponding to a second contrast dose level and a third image corresponding to a third contrast dose level, wherein the first contrast dose level is higher than the second contrast dose level which is higher than the third contrast dose level.

19. The non-transitory computer-readable storage medium of claim 18, wherein the second image is used as ground truth for the training

20. The non-transitory computer-readable storage medium of claim 11, wherein the first input image or the second input image is acquired by a transforming magnetic resonance (MR) device.
